(19) United States
(12) Patent Application Publication
(10) Pub. No.: US 2025/0112172 A1
(43) Pub. Date: Apr. 3, 2025

(54) SEMICONDUCTOR STRUCTURE WITH ELECTROMAGNETIC INTERFERENCE IMMUNITY

(71) Applicant: Apple Inc., Cupertino, CA (US)

(72) Inventors: Michael D. EATON, Cupertino, CA (US); Jing ZHOU, Austin, TX (US); Richard A. MANN, Cupertino, CA (US)

(73) Assignee: Apple Inc., Cupertino, CA (US)

(21) Appl. No.: 18/616,704

(22) Filed: Mar. 26, 2024

Related U.S. Application Data
(60) Provisional application No. 63/586,740, filed on Sep. 29, 2023.

(51) Int. Cl. H01L 23/552

(52) U.S. Cl. CPC H01L 23/552

(57) ABSTRACT

The present disclosure describes a structure that includes an electromagnetic interference (EMI) immunity layer and a doped epitaxial layer on the EMI immunity layer. The EMI immunity layer has a first resistivity and a first thickness. The doped epitaxial layer has a second resistivity and a second thickness. A sum of thicknesses is defined by a combination of the first thickness and the second thickness. A first ratio is the sum of the first thicknesses to the second thickness. A second ratio is the second resistivity to the first resistivity. A product of the first ratio and the second ratio is equal to or less than about 1.

### CROSS-REFERENCE TO RELATED APPLICATION

This application claims the benefit of U.S. Application No. 63/586,740, filed on Sep. 29, 2023, which is incorporated by reference herein in its entirety.

### FIELD

This disclosure relates to methods to achieve immunity to electromagnetic interference (EMI) in sensitive electronic devices. EMI immunity can be achieved by design of a silicon wafer on which integrated circuits are fabricated and mechanically supported when packaged as part of an overall system.

### BACKGROUND

Semiconductor integrated circuits (IC) for sensitive analog applications, such as measurement and sensing, are often used in portable electronic devices. Many portable systems, such as cell phones, also generate strong electromagnetic signals for communications. Strong electromagnetic fields from certain components in the system can unintentionally couple into a sensing device and disturb the intended function of the IC. Techniques to reduce the disturbance can include internal filters, shielding, and placement of sensitive components relative to emitters of strong high frequency electromagnetic fields.

### SUMMARY

The present disclosure is directed to a method and a structure to address disturbances caused by electromagnetic signals in semiconductor devices by designing a wafer substrate (e.g., with sensitive analog devices formed thereon) to confer increased immunity to the disturbances.

Embodiments of the present disclosure include a structure having an electromagnetic interference immunity layer and a doped epitaxial layer on the electromagnetic interference immunity layer. The electromagnetic interference immunity layer has a first resistivity and a first thickness. The doped epitaxial layer has a second resistivity and a second thickness. A sum of thicknesses is defined by a combination of the first thickness and the second thickness. A first ratio is the sum of thicknesses to the second thickness. A second ratio is the second resistivity to the first resistivity. A product of the first ratio and the second ratio is equal to or less than about 1.

Embodiments of the present disclosure include a semiconductor device having a support substrate and a device layer. The support substrate includes an electromagnetic interference immunity layer having a first resistivity and a first thickness. The device layer is in contact with the interface with the support substrate. The device layer includes one or more circuit elements disposed in a doped epitaxial silicon layer having a second resistivity and a second thickness. A sum of thicknesses is defined by a combination of the first thickness and the second thickness. A first ratio is the sum of thicknesses to the second thickness. A second ratio is the second resistivity to the first resistivity. A product of the first ratio and the second ratio is equal to or less than about 1.

Embodiments of the present disclosure include a method for fabricating a semiconductor structure. The method includes forming a doped epitaxial layer on a support substrate comprising an electromagnetic immunity layer. The electromagnetic immunity layer has a first resistivity and a first thickness. The doped epitaxial layer has a second resistivity and a second thickness. A sum of thicknesses is defined by a combination of the first thickness and the second thickness. A first ratio is the sum of thicknesses to the second thickness. A second ratio is the second resistivity to the first resistivity. A product of the first ratio and the second ratio is equal to or less than about 1. The method also includes forming one or more circuit elements in the doped epitaxial layer.

### BRIEF DESCRIPTION OF THE DRAWINGS

Embodiments of the present disclosure are best understood from the following detailed description when read with the accompanying figures. It is noted that, according to the standard practice in the industry, various features are not drawn to scale. Features of the present disclosure can be illustrated having larger and/or smaller dimensions for clarity of discussion.

FIGS. 1A and 1B show illustrations of semiconductor devices, according to some embodiments.

FIG. 2 shows an illustration of an on-chip semiconductor circuit, according to some embodiments.

FIG. 3 shows an illustration of another on-chip semiconductor circuit, according to some embodiments.

FIG. 4 shows an illustration of a semiconductor structure, according to some embodiments.

FIG. 5 shows a flow chart of a method for fabricating a semiconductor structure, according to some embodiments.

FIGS. 6A-6D show illustrations of a semiconductor device at various stages of the method in FIG. 5, according to some embodiments.

FIG. 7 shows a flow chart of a method for processing a semiconductor structure, according to some embodiments.

FIGS. 8A-8D show illustrations of a semiconductor device at various stages of the method in FIG. 7, according to some embodiments.

FIG. 9 shows a flow diagram for modifying a mechanical support element after completion of IC manufacturing operations, according to some embodiments.

FIG. 10 shows an illustration of various exemplary systems or devices that can include the disclosed embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides different embodiments, or examples, for implementing different features of the provided subject matter. Specific examples of components and arrangements are described below to simplify the present disclosure. These are merely examples and are not intended to be limiting. The present disclosure can make use of reoccurring reference numerals and/or letters in the various examples. This repetition is for the purpose of simplicity and clarity and, unless indicated otherwise, does not in itself indicate a limiting relationship between the various embodiments and/or configurations discussed.

It is noted that references in the specification to “one embodiment,” “an embodiment,” “an example embodiment,” “exemplary,” and the like, indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

In the description of at least some embodiments herein, enumerative adjectives (e.g., “first,” “second,” and “third”) can be used to distinguish like elements without establishing an order, hierarchy, quantity, or permanent numeric assignment (unless otherwise noted). For example, the terms “first resistor” and “second resistor” can be used in a manner analogous to “i^{th} resistor” and “j^{th} resistor” so as to facilitate identification of two or more resistors without specifying a particular order, hierarchy, quantity, or immutable numeric correspondence.

It is to be understood that the phraseology or terminology herein is for the purpose of description and not of limitation, such that the terminology or phraseology of the present specification is to be interpreted by those skilled in relevant art(s) in light of the teachings herein.

The following disclosure describes embodiments directed to semiconductor devices with increased immunity to EMI. ICs on semiconductor substrates can be susceptible to high-frequency (e.g., RF) magnetic fields. To address this challenge, embodiments of the present disclosure are directed to a semiconductor structure that mitigates (or eliminates) the negative effects of high-frequency EMI.

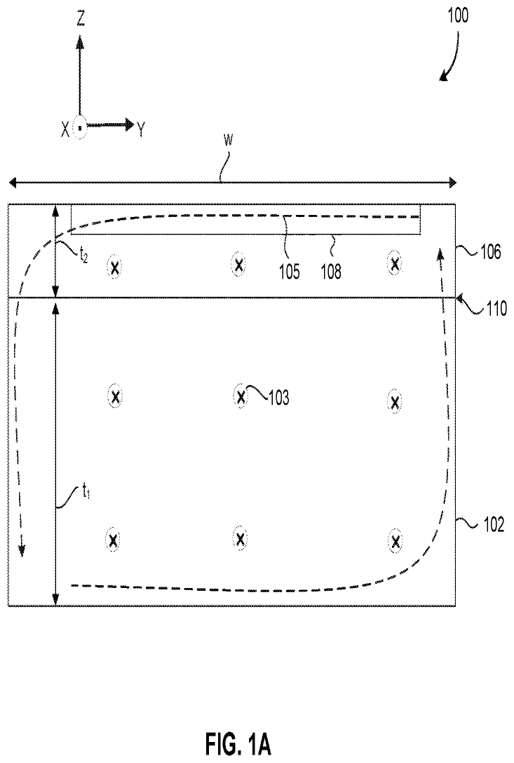

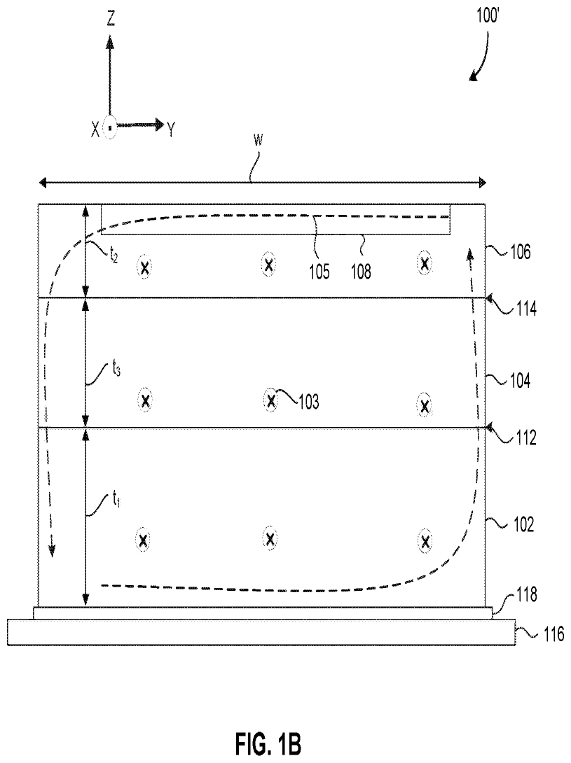

FIG. 1A shows an illustration of a semiconductor device (or “semiconductor structure”) 100, according to some embodiments. In some embodiments, semiconductor device 100 includes a support substrate 102 and a device layer 106. Device layer 106 is disposed on (e.g., formed on) support substrate 102. An interface 110 denotes an interface between support substrate 102 and device layer 106. Support substrate 102 can be a semiconductor wafer used in complementary metal-oxide semiconductor (CMOS) processing, such as a p-doped silicon wafer. Support substrate 102 has a first thickness t₁ (e.g., in the z-direction), a first resistivity ρ₁, and a first dopant concentration (or “dopant level”). Resistivity and dopant concentration are related parameters (e.g., higher net doping of same polarity). The term “resistivity” used in the description of some embodiments herein can refer to the concept of specific net doping value or profile of values, which can include a constant or nearly constant net doping, but can also reference a net doping profile. Device layer 106 has a second thickness t₂, a second resistivity ρ₂, and a second dopant concentration. Support substrate 102 provides mechanical support and electronic characteristics for other layers and electronic devices fabricated on support substrate 102. For mechanical support, first thickness t₁ can have an initial thickness of about 750 μm and can be thinned as part of a packaging process, according to some embodiments. Therefore, first thickness t₁ can be in the range of about 705 μm to about 795 μm during initial processing to form and verify the circuit elements. A wide range of first thickness t₁ or mechanical support thickness can be supported when the final device is delivered in packaged from the range of about 705 μm to about 795 μm to a thinned support as thin as about 80 μm.

In the packaged form as delivered for use, first thickness t₁ can be provided according to various ranges, for example, about 100 μm to about 700 μm, about 100 μm to about 500 μm, about 100 μm to about 400 μm, about 100 μm to about 300 μm, about 100 μm to about 200 μm, or about 100 μm to about 120 μm. The description of distinct layers illustrated with interface 110 is for the purpose of illustration. A gradual transition of properties from diffusion of extended doping levels can occur over a transition region whose scale is small compared to the total distance illustrated at the sum of t₁+t₂. This transition can be about 3/750 to about 10/750 ratio to the total thickness t₁+t₂.

In some embodiments, electronic components in the vicinity of device layer 106 (and/or electronic components of device layer 106) can generate EMI-causing signals. An effect of EMI is the creation of induced current loops in semiconductor device 100. As illustrated in FIG. 1A, a magnetic field 103 (e.g., EMI-causing signal) is indicated by several vector-into-page symbols (circle-crosses). Magnetic field 103 can switch at ultra-high speeds (e.g., greater than about 5 GHZ) and can be considered high frequency noise. Magnetic field 103 can induce an electromotive force (EMF). The EMF can induce a current loop having a direction indicated by the dashed arrows. The interfering component of the current loop is a surface eddy current 105, which can parasitically couple to electronic components of device layer 106. The interaction between surface eddy current 105 and electronic components of device layer 106 can disrupt the functions of semiconductor device 100.

In some embodiments, semiconductor device 100 can be a chip having a width w. The cross-sectional area of the chip is equal to w×(t₁+t₂). In the illustrated example, magnetic field 103 is perpendicular to the cross section. The intensity of surface eddy current 105 is influenced by at least the following: (A) a change in magnetic field 103, (B) the cross-sectional area through which magnetic field 103 is acting upon (e.g., more area has more flux), and (C) the number of free charges (or carriers) available to move in response to the induced EMF. Reduction of any of A, B, or C reduces the intensity of surface eddy current 105 and therefore reduces the effects of EMI. For example, reducing t₁ by thinning a substantial portion of support substrate 102 (e.g., by back-grinding and/or polishing) reduces the cross-sectional area, thereby reducing the magnitude of magnetic induction in semiconductor device 100. Using a high-resistivity support substrate 102 can reduce surface eddy current 105. Support substrate 102 can be a high resistivity silicon substrate to confine the current loop to within device layer 106, thereby reducing the flux (e.g., the considered area is only w×t₂ as opposed to w×(t₁+t₂)) and in turn reducing the impact from EMI.

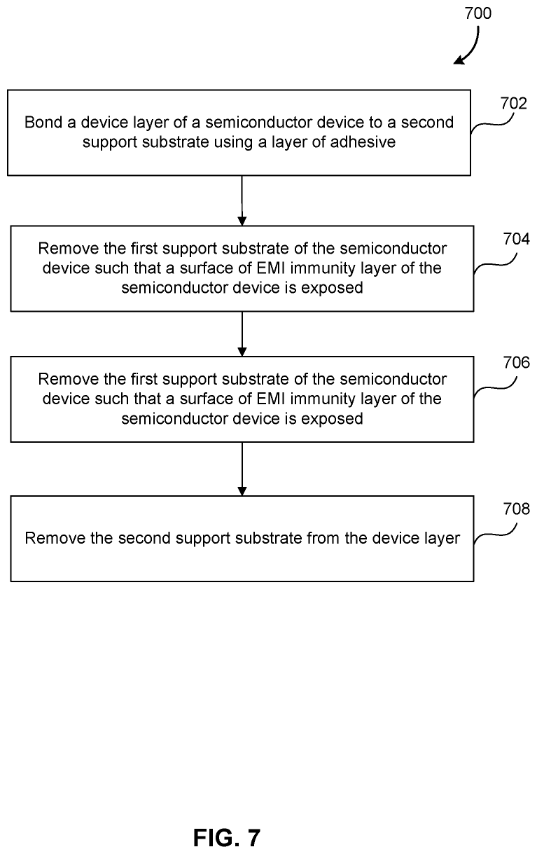

In some embodiments, support substrate 102 for electromagnetic immunity mechanical support can have extremely high resistivity or be intrinsic silicon with very low net doping concentrations (e.g., less than about 1×10¹² atoms/cm³). Near intrinsic silicon with net doping levels of about 2×10¹² atoms/cm³ can have a resistivity of about 10,000 Ω-cm. The resistivity of undoped or lightly doped silicon can be about 1000 times or more higher than a CMOS starting wafer having a resistivity in the range of about 5 Ω-cm to about 10 Ω-cm, according to some embodiments. EMI immunity can be implemented with minimum disturbance to mass fabrication methods for manufacture of the active devices in device layer 106 by replacing the portion of the wafer used for mechanical support in device fabrication with a new support substrate for packaging, as illustrated in FIGS. 7-9.

In some embodiments, the lowest recurring cost introduction of an EMI immunity layer for device layer 106 is to modify the starting wafer used for the IC manufacture. The modification of the starting wafer can be achieved by adjusting the vertical doping profile of either of the starting wafer or an intervening layer (an intervening layer is described in reference to FIG. 1B).

In some embodiments, support substrate 102 can be a substrate with a predetermined resistivity. A specifically designed layer (e.g., device layer 106) can be fabricated on support substrate 102, with support substrate 102 providing mechanical support. The doping layer and thickness of the specifically designed device layer 106 can be selected to be compatible with process flows and electrical properties for the device elements of the IC (e.g., an application-specific integrated circuit (ASIC)). From an EMI standpoint, a high-resistivity support substrate 102 is desirable to mitigate the effects of EMI. However, implementing the high-resistivity support substrate 102 can be challenging in terms of cost and burden of modifying an established fabrication process to accommodate the high-resistivity support substrate. For example, consider a fabrication facility for manufacturing device layer 106 on a heavily doped CMOS wafer (e.g., doped so as to have a low resistivity of about 0.03 Ω-cm). Heavily doped support substrates can have advantages related to electrical overstress characteristics (e.g., latch up) and control of impurities in the manufacturing process. Heavily-doped substrate wafers that can be used as support substrate 102 can have very low resistivities (e.g., about 0.03 Ω-cm) while device fabrication layers (e.g., device layer 106) can be doped (e.g., doping level of about 1×10¹⁷ cm⁻³) to resistivity values in the range of about 5 Ω-cm to about 10 Ω-cm. In other words, the resistivity of support substrate 102 can be over 100 times less than a resistivity of device layer 106, over 200 times less than a resistivity of device layer 106, or over 300 times less than a resistivity of device layer 106. In this scenario, the cost and manufacturing logistics to modify the existing fabrication process (e.g., tailored to low-resistivity support substrates) so as to work with a high-resistivity support substrate, such as intrinsic silicon, can be challenging.

Therefore, one or more of the disclosed embodiments are based on a relationship between the resistivity (or dopant level) and the cross-sectional area of semiconductor device 100 such that reduction of effects of EMI is achieved while mitigating an adverse impact to wafer level processes for initial circuit manufacturing. As described above, a cross-sectional area of semiconductor device 100 and resistivity of the layers of semiconductor device 100 can influence EMI susceptibility. A figure of merit is defined as a contribution C—that is, the contribution of support substrate 102 to the induced EMF when magnetic field 103 drives through the cross section of the chip. The contribution C is defined as a ratio of the cross-sectional area of support substrate 102 and device layer 106 (w×(t₁+t₂)) to the cross-sectional area of device layer 106 (w×t₂) times a ratio of the resistivity ρ₂ of device layer 104 to the resistivity ρ₁ of support substrate 102. After cancellations, the contribution C is given by equation 1:

$$C = [ ( {t}_{1} + {t}_{2} ) / {t}_{2} ] * {ρ}_{2} / {ρ}_{1} . \qquad Eq . 1$$

The value range of contribution C can start at zero and has no upper bound (a lower value is better). For example, for an ideal infinitely resistant support substrate 102, contribution C goes to zero as ρ₁ goes to infinity (theoretical/mathematical limit). It was noted above that high-resistivity support substrates can cause problems in the cost and manufacturing logistics of fabricating semiconductor device 100. Therefore, in some embodiments, the values of t₁, t₂, ρ₁, and ρ₂ can be arranged such that the contribution C is equal to or less than about 0.1. Put differently, a sum of thicknesses (t₁+t₂) can be described as a combination of first thickness t₁ and second thickness t₂. A first ratio is the sum of thicknesses (t₁+t₂) to second thickness t₂. A second ratio is second resistivity ρ₂ to the first resistivity ρ₁. Then, the contribution C, which is a product of the first ratio and the second ratio, is equal to or less than about 0.1. For example, during fabrication of support substrate 102, dopant levels can be reduced such that first resistivity ρ₁ is increased (e.g., in comparison to a heavily doped CMOS wafer), thereby improving EMI immunity of a device to be fabricated on support substrate 102. Rather than allowing first resistivity ρ₁ to increase unbounded, first resistivity ρ₁ is limited to a given value such that, when first thickness t₁ is accounted for in a final packaging of the device, the contribution C conforms to the conditions set above (e.g., equal to or less than about 0.1).

A cost-effective solution to test the effectiveness of EMI immunity using one or more embodiments described herein can include estimating EMI impact using device and circuit simulations with or without correlation to measured EMI effects during product design. EMI hardening performance can be estimated in advance of fabrication of circuits according to one or more embodiments described herein. Robust integrations of the electromagnetic immunity layer can be estimated prior to expensive fabrication. Greater freedom in system designs can be achieved, while maintaining performance according to desired tolerances in sensitive devices.

In some embodiments, the contribution C can be equal to or less than about 10, equal to or less than about 1, equal to or less than about 0.5, equal to or less than about 0.3, equal to or less than about 0.01, or equal to or less than about 0.001. Different values of C have technical significance. For example, when setting the thicknesses and resistivities for a given value of C, tradeoffs in advantages and drawbacks can be considered. Let a range of support substrate configurations define a range of surface EMF (e.g., EMI) that can be contributed by the support substrate. Let a best-case support substrate (e.g., a thick wafer of intrinsic silicon) define the lower bound of the range of surface EMFs (e.g., best-case surface EMF). Then, in the case of C being about 0.1 or less, support substrate 102 contributes to EMI by an additional 10% compared to the best-case surface EMF (lower percentage is better, lower EMI). The reduction in EMI is then weighed against the increased cost associated with fabricating a thick high resistivity support substrate. On the other hand, in the case of C being on the higher end of about 1 or less, support substrate 102 contributes to EMI by an additional 50% compared to the best-case surface EMF. While the EMI from this configuration is higher than before, the manufacturing process can be relaxed and less constrained (e.g., can allow a more cost-effective fabrication of a thinner high resistivity support substrate).

In this manner, support substrate 102 is designed to provide increased immunity to EMI while the portion of support substrate 102 used in fabrication of active devices maintains desirable properties for the base fabrication of the ICs. At least a portion of the original fabrication wafer (e.g., after back-grinding of support substrate 102) can remain in the final packaging of the chip. The portion of support substrate 102 that remains present in the final packaging can have higher resistivity than the epitaxial layer in which the active circuits are fabricated for increased EMI immunity.

FIG. 1B shows an illustration of a semiconductor device 100′, according to some embodiments. In some embodiments, semiconductor device 100′ includes structures that are the same or substantially similar to those in semiconductor device 100 of FIG. 1A, such as support substrate 102 and device layer 106. However, semiconductor device 100′ also includes an EMI immunity layer 104. As explained above in reference to FIG. 1A, it is desirable to implement a high-resistivity support substrate so as to mitigate EMI at one or more circuit elements 108 of device layer 106. EMI immunity layer 104 can have a very high resistivity (e.g., over 10 times greater than the resistivity of device layer 106 or about 1×10² to about 1×10⁴ Ω-cm). EMI immunity layer 104 can approach the limiting case of near intrinsic silicon with doping levels below a net practical value of about 1×10¹² atoms/cm³. While achieving true intrinsic silicon may be desirable, it can be difficult due to background levels of doping present in epitaxy reactors. For maximum EMI immunity, dedicated epitaxy reactors can be used for electromagnetic immunity or counter doping with opposite polarity doping can be used to achieve very high resistivity. In some embodiments, full optimization of the manufacturing methods can achieve a resistivity of about 3000 Ω-cm at about 300 K temperature. Net doping levels of about 1×10¹⁴ atoms/cm³ (e.g., corresponding to 150 Ω-cm) can be achieved without significant changes to fabrication methods, which can provide about 490 times improvement in EMI immunity as compared to using a low resistivity CMOS starting wafer without an intervening EMI immunity layer 104.

In some embodiments, EMI immunity layer 104 has a third thickness t₃, a third resistivity, and a third dopant concentration. Third thickness t₃ (e.g., in the z-direction) is different from first thickness t₁ of support substrate 102. The value of third thickness t₃ can be chosen so as to provide a mechanical support layer of high resistivity to be included as part of the final packaging with semiconductor device 100′. Hence, semiconductor device 100′ can have greater RF immunity by reducing surface eddy current 105 induced by strong parasitic electromagnetic fields, such as magnetic field 103. The presence of EMI immunity layer 104 acts as a resistive path for the induced EMF and therefore reduces the intensity of surface eddy current 105.

In some embodiments, third thickness t₃ is designed to provide mechanical support for subsequent packaging operations. For example, third thickness t₃ can be chosen so that, when support substrate 102 is thinned and/or removed, mechanical support is provided by EMI immunity layer 104 and semiconductor device 100′ fits into a chip package. EMI immunity layer 104 can be disposed on support substrate 102 by epitaxial growth. It is desirable to set a target thickness, in consideration of manufacturing tolerances, so as to grow to the target thickness and to avoid an unnecessary expense associated with growing a thicker layer.

In some embodiments, a goal in designing a base wafer starting material for ICs is to provide EMI immunity layer 104 as part of the base wafer with minimum to no disruption to important attributes of support substrate 102 and device layer 106. The base wafer provides mechanical support through the manufacturing process. Hence, it is desirable for the base wafer to contribute to the total thickness of the aggregated layers to be compatible with handling processes during fabrication. Furthermore, specific doping properties and/or trace impurity properties (e.g., trace oxygen concentration) can be used for electrical conductivity during manufacture and gettering of impurity levels (e.g., trace metal contaminants). Therefore, the retention of these properties of support substrate 102 can be relevant to the success of the IC fabrication process. Epitaxial growth of EMI immunity layer 104 and device layer 106 on top of a suitable support substrate wafer with properties suitable for the fabrication technology can achieve the desired EMI immunity effect with minimum disruption to fabrication processes, according to some embodiments. An epitaxially prepared starting wafer can have, for example, a total thickness of about 725 μm to about 775 μm, a low resistivity support substrate 102 (e.g., about 0.05 Ω-cm resistivity or lower) upon which a thin (e.g., about 4 μm to about 20 μm) higher resistivity surface layer is grown (e.g., about 5 Ω-cm to about 10 Ω-cm) for device formation. This combination has a number of advantages for the quality and yield of IC devices, but this layer configuration can be challenging for electromagnetic immunity.

Practical considerations of the art of semiconductor manufacture (e.g., cost, convenience, mechanical stability, gettering properties for impurities in the original manufacture of the circuit layer) can limit the ability to implement a thick layer support substrate 102 that has very low doping levels. Significant change in the doping levels of the starting wafer can trigger an extensive qualification to determine the risks and benefits for deviation from a CMOS starting wafer that has a low resistivity. The reduction of doping levels to increase resistivity immediately below device layer 104 can still provide significant advantages in EMI immunity when compared to a CMOS starting wafer. For many CMOS and bipolar technologies, device construction can depend upon doping levels added to the starting wafer and be largely unaffected by the relatively low concentrations of doping in the starting wafer. In this case, replacing the starting CMOS wafer with a highly doped substrate having a low doped layer (e.g., of about 1×10¹⁴ atoms/cm³ and a thickness of about 20 Ω-cm to about 40 μm) upon the highly doped substrate can provide significant improvement in EMI immunity with minimum interference with the benefits of providing a volume of high resistivity material proximal to device layer 106, while allowing fabrication on a low resistivity substrate.

In some embodiments, an optimal thickness of EMI immunity layer 104 can depend upon the constraints of the planned packaging method for semiconductor device 100′. FIG. 1B can represent an embodiment in which a very thin EMI immunity layer 104 is interposed on the layer structure of semiconductor device 100′, between device layer 106 and support substrate 102 or a remaining portion of support substrate 102 after thinning. In the case of support substrate 102 having a very low resistivity (e.g., heavily doped), grounding of support substrate 102 can be achieved robustly through a connection to the floor of a final package support 116. The currents generated by EMI-causing electromagnetic fields (e.g., magnetic field 103) results in a low potential gradient in support substrate 102, which is isolated from the device layer 106 due to the high resistivity of the intervening EMI immunity layer 104.

In some embodiments, a sum of the first thickness t₁ and third thickness t₃ provide sufficient mechanical support for packaging with a total thickness in the range of about 60 μm to about 200 μm. This approach reduces the cost of the epitaxial growth of EMI immunity layer 104 upon the starting wafer. However, as mentioned above, some embodiments can have support substrate 102 completely removed and EMI immunity layer 104 can provide the entire thickness of the mechanical support for die packaging. In this scenario, for safe die handling for packaging, third thickness t₃ can be in the range of about 80 μm to about 200 μm, about 80 μm to about 150 μm, about 80 μm to about 100 μm, about 100 μm to about 200 μm, or about 150 μm to about 200 μm. The currents induced in EMI immunity layer 104 are suppressed due to the high resistivity. An interface 112 denotes an interface between support substrate 102 and EMI immunity layer 104. An interface 114 denotes an interface between EMI immunity layer 104 and device layer 106. The interfaces are illustrated as “lines” for simplicity of exposition. The transition between net doping levels can occur gradually over a finite distance.

In some embodiments, it is desirable for EMI immunity layer 104 to be made of near intrinsic silicon (e.g., near zero net dopants or less than about 1×10¹² atoms/cm³) and the third resistivity ρ₃ can be in a range of about 102 Ω-cm to about 10⁴ Ω-cm (e.g., greater than about 200 kΩ-cm. However, as explained above regarding epitaxial layer growth impose practical challenges. Therefore, when implementing EMI immunity layer 104, it is envisaged to adjust the third thickness t₃ and third resistivity ρ₃ according to the relationship described above in terms of equation 1 (substituting ρ₁ with ρ₃ and substituting t₁ with t₃ in equation 1). It is to be appreciated that, in FIG. 1A, support substrate 102 can be considered as an EMI immunity layer because the design of support substrate 102 of FIG. 1A is based on the relationship described above in terms of equation 1, which provides enhanced EMI immunity. Furthermore, as an alternative description of FIG. 1B, a substrate for EMI-reduction and mechanical support can comprise a first support layer (e.g., EMI immunity layer 104) and a second support layer (e.g., support substrate 102). A proportional benefit of RF immunity is achieved by reducing doping levels (e.g., from about 2×10¹⁵ atoms/cm³ to about 5×10¹⁵ atoms/cm³ or from about 3 Ω-cm to about 8 Ω-cm) towards 1×10¹⁴ atoms/cm³ or about 150 Ω-cm). Net doping levels of 1×10¹³ atoms/cm³ can achieve a substantially higher resistance (e.g., about 1450 Ω-cm or about a 3400 times reduction in substrate currents induced by magnetic field 103).

In some embodiments, the physical change in doping levels is not abrupt. A reason is that mixing and inter-diffusion occur during creation of epitaxial layers on silicon substrates. And further mixing by diffusion occurs as a result of thermal treatments in the manufacture of the IC on the starting support substrate that has been prepared according to embodiments of the present disclosure. The inter-diffusion can be taken into account during the design of device layer 106, which can be thinner (e.g., about 3 μm to about 20 μm) than the mechanical support silicon for packaging (e.g., about 60 μm to about 200 μm). In an embodiment in which support substrate 102 is a silicon CMOS base wafer (e.g., low resistivity), EMI immunity layer 104 can be made of high-resistivity silicon and device layer 106 can be an epitaxial layer of silicon with a dopant concentration suitable for one or more circuit elements 108 to be fabricated thereon (e.g., one or more passive devices, active devices, transistors, and interconnects). This approach allows for minimum disruption or interference with design, manufacturing, and yield of the IC element by reducing the scope of changes made to portions of the starting support substrate that function as a mechanical support for processing and subsequent packaging.

Goals in the design and fabrication of a custom wafer with EMF immunity layer 104 can include at least the following three goals:
(1) Improvements in RF EMI immunity for the IC in the product application by reducing substrate currents from external electromagnetic fields (e.g., by having a mechanical support for packaging of high resistivity).
(2) Minimizations in change of form, fit, function, reliability, and yield of ICs fabricated on the custom wafer with EMF immunity layer 104 by maintaining substantially identical physical and electrical properties of device layer 106 in which one or more circuit elements 108 are fabricated. Terms such as “layer,” “zone,” or “region” can be used interchangeably. And, while interfaces 110, 112, and 114 are indicated in FIGS. 1A and 1B to facilitate description of the layered structure, it is to be understood that interfaces between two layers can be gradual due to, for example, transition of doping levels as gradients resulting from inter-diffusion.
(3) Minimizations in degradation of mechanical/physical, electrical, and defect/imperfection properties of the silicon wafer during the manufacturing process. A role of the thickness of the silicon wafer is to provide a stable mechanical platform for the processing of subsequent device fabrication on the silicon wafer to create the IC functionality on the top surface of the silicon wafer. A sufficient thickness ensures that the silicon wafer remains sufficiently flat during processing for lithography tools to print masks, ensures that the silicon wafer collects certain harmful impurities away from the surface device layer (e.g., device layer 106), and ensures that the silicon wafer does not shatter or crack during the mechanical and thermal stress of fabrication processes. In embodiments directed to FIG. 1B, the properties of a portion of the bulk support substrate 102 are modified so as to have a high-resistivity layer (e.g., EMI immunity layer 104) in direct contact with device layer 106. It is to be appreciated the arrangement in FIG. 1B presents trade-offs in terms of cost and device performance. For example, insertion of EMI immunity layer 104, having a third thickness t₃ of about 20 μm to about 100 μm, a fraction of a total thickness of a starting wafer (e.g., about 750 μm) will be effective at providing enhanced RF EMI immunity.

In some embodiments, FIG. 1B can represent a packaged state of semiconductor device 100′ after thinning (e.g., by back grinding and polishing) and addition of a final package support 116 after completion of IC processing. Final package support 116 provides mechanical stabilization and electrical connections. EMI immunity layer 104 can also contribute to the mechanical support function (e.g., having a third thickness t₃ of about 60 μm to about 400 μm) for one or more circuit elements 108 at device layer 106.

FIG. 1B is directed to embodiments that allow a thinner high-resistivity layer (as compared to FIG. 1A) for providing RF immunity protection. A thin high-resistivity layer, such as EMI immunity layer 104, is grown by epitaxy on support substrate 102. Depending on the target value for third thickness t₃, EMI immunity layer 104 can be insufficient to provide mechanical support for packaging operations that follow. This insufficiency can be addressed by implementing support substrate 102, in which the thinner EMI immunity layer 104 reduces costs and is less potentially disruptive to other properties of the starting wafer on which EMI immunity layer 104 is grown. Hence, support substrate 102 can have a thickness that is about 2 times greater than the thickness of EMI immunity layer 104, about 4 times greater than the thickness of EMI immunity layer 104, about 5 times greater than the thickness of EMI immunity layer 104, about 10 times greater than the thickness of EMI immunity layer 104, or about 20 times greater than the thickness of EMI immunity layer 104. Additionally, there is also potential to reduce costs and delays associated with qualification or acceptance of alternate starting wafers at the IC wafer factory. Since the problem of surface eddy current 105 is addressed by the presence of EMI immunity layer 104, there is more freedom to choose different kinds of starting wafers; for example, a p-epitaxial on a p+ substrate can be used. The p+ substrate can provide advantageous properties for fabrication with an epitaxially grown p-layer (e.g., with a thickness between about 7 μm and about 20 μm).

A problem can arise during fabrication of custom layers using epitaxy on silicon substrates to form wafers layers of high resistivity from background contamination in an epitaxial reactor. Contaminants can be present in the epitaxial reactor from the dopant species most commonly applied in significant concentration. To fabricate high resistivity layers, some embodiments can implement more than one epitaxial reactor or specific epitaxial reactors. An optional method with cost and performance advantages is to use implantation steps inserted into an epitaxial growth sequence to achieve an EMI immunity layer at a lower total cost for the similar high effective resistivity. The following is example process sequence.

In some embodiments, epitaxial addition can begin on a highly doped (e.g., P+) starting wafer. This starting epitaxial addition can become the EMI immunity layer with high resistivity upon which a device layer is formed. The device layer can have a net p-type doping resulting in a resistivity of about 5-10 Ω-cm and thickness of about 4 μm to about 20 μm.

In some embodiments, the starting portion (e.g., approximately half of the target thickness of the EMI immunity layer) can have a target highest resistivity that the background concentration of dopant in the epitaxial reactor will allow (e.g., background dopant can be boron). For example, depending on the background contaminant in the epitaxial reactor, a dopant concentration of about 5×10¹⁴ atoms/cm³ can be achieved in the starting portion of the EMI immunity layer.

In some embodiments, the epitaxial addition can be stopped in preparation to add a net n-type doping. For example, epitaxial growth in the epitaxial reactor can be continued in a reactor with n-type dopants and/or n-type dopant can be implanted. If the fabrication process relies on wafers to be grounded through the wafer backside, in critical steps, the n-type implantation can be masked such that n-type implantation is avoided at specific locations, such as the extreme wafer edge.

In some embodiments, the wafer can then be transferred to a desired epitaxial reactor to continue growth of the EMI immunity layer. Device layer growth can also continue here via adjustment of dopant flows.

In some embodiments, subsequently when the layered wafer is processed through IC fabrication processes, the bulk of the mechanical support element of the wafer will have suitable mechanical, physical, and electrical properties. The heating and annealing of the wafer to activate the n-type dopants added in the EMI immunity layer will diffuse the n-type dopants during wafer processing, thereby counter-doping the unwanted trace p-type dopants. Furthermore, any deliberate concentration of net n-type doping will form a depletion region with the net p-type doping. The depletion region is a region of high resistivity. This method can achieve a high resistivity zone in the wafer with a modest inconvenience and low cost.

The above noted operations allow for one or more desirable features for a layered wafer with improved EMI immunity. In some embodiments, the device layer has a doping profile that is optimized for IC elements of high quality and high yield without having to deviate significantly from an existing wafer-processing recipe. Using the epitaxial scheme described above, the EMI immunity layer with a higher resistivity can be formed in direct contact with the device layer. The resistivity of the EMI immunity layer can be increased by use of counter doping through implantation and/or change of reactant during epitaxial deposition. Furthermore, the counter doping method can be used to create a depletion region with a high resistivity.

Support substrate 102 can then be thinned for packaging, leaving a sufficient portion of support substrate 102. The portion responsible for mechanical support is characterized by the sum of first thickness t₁ and third thickness t₃. The high resistivity of EMI immunity layer 104 suppresses the formation of surface eddy current 105 from magnetic field 103 in proximity to device layer 106. By contrast, even though support substrate 102 can be chosen to be of low resistivity owing to the EMI-suppressing presence of EMI immunity layer 104, induced currents in support substrate 102 can be addressed by including a backside contact layer 118. In this manner, the potential differences induced in support substrate 102 can be minimized. The ground potential of support substrate 102 can be maintained due to the low resistance contact to final package support 116 through contact layer 118. Hence, the disturbance of potentials in device layer 106 can be minimized, while allowing the high-resistivity EMI immunity layer 104 to be thinner.

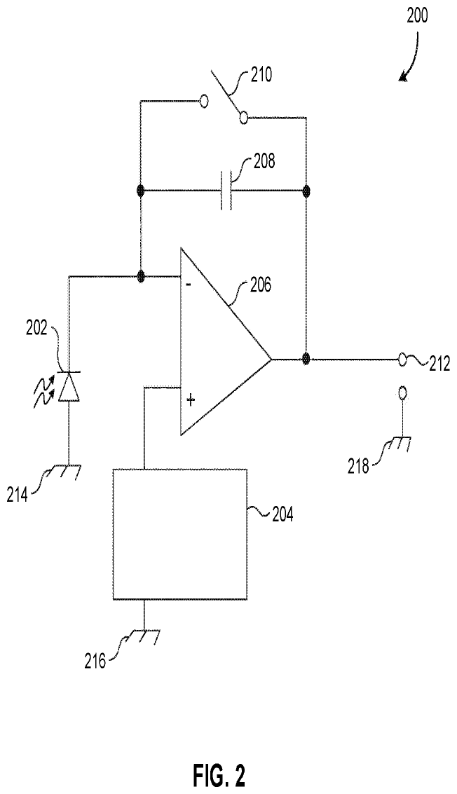

FIG. 2 shows an on-chip integrated circuit 200, according to some embodiments. In some embodiments, the circuit elements of on-chip integrated circuit 200 can represent one or more circuit elements 108 disposed in/on device layer 106 in FIGS. 1A and 1B. The layering of semiconductor structure 100′ in FIG. 1B with EMI immunity layer 104 (or semiconductor structure 100 in FIG. 1A with high-resistivity support substrate 102) is suitable for reducing noise and EMI of on-chip integrated circuit 200.

On-chip integrated circuit 200 is a photodetector with an amplifier, according to some embodiments. On-chip integrated circuit 200 includes a photodiode 202, a zeroing circuit 204, an amplifier 206, a capacitor 208, a shunt switch 210, an output 212, and ground connections 214, 216, and 218. Photodiode 202 generates a current based on detected photons. Photodiode 202 is connected to one of the inputs of amplifier 206. Amplifier 206 amplifies the current/voltage generated by photodiode 202. Zeroing circuit 204 is connected to another one of the inputs of amplifier 206 to mitigate offsets, drift, and/or 1/f noise. Capacitor 208 and shunt switch 210 are disposed in a feedback path of amplifier 206 for phase margin and stability control. Output 212 outputs an amplified signal that corresponds to the detection of photons at photodiode 202. Ground connections 214, 216, and 218 provide a ground reference for on-chip circuit integrated circuit 200.

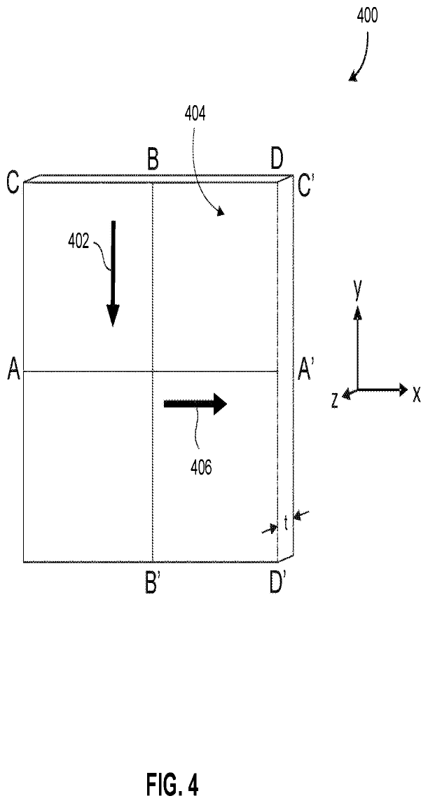

In some embodiments, a photodiode current from photodiode 202 can be very small. An external voltage across photodiode 202 of a few microvolts (e.g., from EMI) can appear as increased output noise at output 212, causing inaccurate readings. Hence, the EMI current/voltage reduction afforded by the layered structure in FIGS. 1A and 1B, which can have a reduction greater than about 95% (explained in reference to FIG. 4), can greatly reduce signal noise of on-chip integrated circuit 200 and enhance device reliability and accuracy.

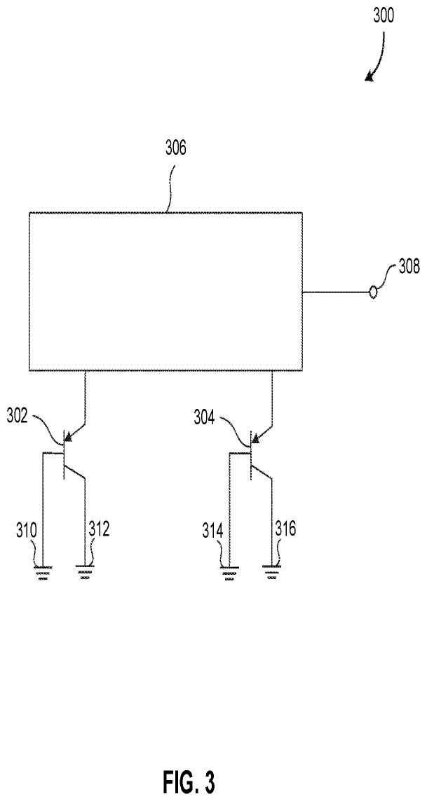

FIG. 3 shows an on-chip integrated circuit 300, according to some embodiments. In some embodiments, the circuit elements of on-chip integrated circuit 300 can represent one or more circuit elements 108 disposed in/on device layer 106 in FIGS. 1A and 1B. The layering of semiconductor structure 100′ in FIG. 1B with EMI immunity layer 104 (or semiconductor structure 100 in FIG. 1A with high-resistivity support substrate 102) is suitable for reducing noise and EMI of on-chip integrated circuit 300.

On-chip integrated circuit 300 is a temperature sensor with bipolar junction transistors (BJTs), according to some embodiments. On-chip integrated circuit 300 includes a first transistor 302, a second transistor 304, a temperature-sensing circuit 306, an output 308, and ground connections 310, 312, 314, and 316. Transistors 302 and 304 are BJTs. The current/voltage signal from output 308 includes information about the thermal state of on-chip integrated circuit 300 (e.g., temperature information). Ground connections 310, 312, 314, and 316 provide a ground reference for on-chip circuit integrated circuit 300. In some embodiments, on-chip integrated circuit 300 is a proportional-to-absolute-temperature (PTAT) sensor.

In some embodiments, integrated BJTs can be vulnerable to surface voltage variation due to EMI. Therefore, EMI can adversely impact the current/voltage signal from output 308, causing inaccurate temperature readings. Hence, the EMI current/voltage reduction afforded by the layered structure in FIGS. 1A and 1B, which can have a reduction greater than about 95% (explained in reference to FIG. 4), can greatly reduce signal noise of on-chip integrated circuit 300 and enhance device reliability and accuracy.

In some embodiments, the EMI immunity afforded by the structures disclosed herein are not limited to the circuits shown in FIGS. 2 and 3. It is envisaged that structures of FIGS. 1A and 1B can be implemented in other EMI-susceptible semiconductor devices, which are within the spirit and scope of the present disclosure.

FIG. 4 shows an illustration of a semiconductor structure 400 subjected to a magnetic field 402, according to some embodiments. In some embodiments, a surface 404 of semiconductor structure 400 is oriented facing out of the page (e.g., in the z-direction). Surface 404 is where high-resistivity epitaxial layer (e.g., EMI immunity layer 104) and/or a doped epitaxial layer (e.g., device layer 106) are disposed thereon as per FIGS. 1A and 1B. For example, surface 404 denotes a surface of device layer 106 on which one or more circuit elements 108 are to be formed. EMI immunity layer 104 or high-resistivity support substrate 102 is disposed behind surface 404 (in the z-direction; view obstructed). A low-resistivity support substrate 102, as described in reference to FIG. 1B, can be disposed behind EMI immunity layer 104 (in the z-direction; view obstructed).

Semiconductor structure 400 can have a thickness t (e.g., in the z-direction), which depends on how semiconductor structure 400 is layered. Thicknesses of layers are as described in reference to FIGS. 1A and 1B. If semiconductor structure 400 is support substrate 102 by itself, then thickness t of semiconductor structure 400 is first thickness t₁ as in FIG. 1A. If semiconductor structure 400 includes support substrate 102 with EMI immunity layer 104 only, then thickness t of semiconductor structure 400 is first thickness t₁ plus third thickness t₃ as in FIG. 1B. If semiconductor structure 400 includes support substrate 102 with EMI immunity layer 104 and device layer 106, then thickness t of semiconductor structure 400 is first thickness t₁ plus second thickness t₂ plus second thickness t₃ as in FIG. 1B. Defined along surface 404 are cross sectional lines AA′, BB′, CC′, and DD′ at which a surface current is measured. The surface current arises in response to a magnetic field 402 applied throughout the body of semiconductor structure 400. A current 406 is illustrated for cross sectional line AA′. Other currents that are not illustrated in FIG. 4 should be apparent based on the location of the cross sectional lines. In lieu of using units of currents (e.g., amps), units of voltage for the EMF of the induced current can also be used. A designation for the measured induced EMF voltages at a given cross sectional line can be as follows: V_{AA′}, V_{BB′}, V_{CC′}, and V_{DD′} (e.g., voltage amplitude). Magnetic field 402 can be set to a high switching speed or frequency (e.g., 3 GHZ) and a predetermined amplitude (e.g., 1 A/m).

For discussing the effects of EMI suppression, three different layer arrangements are defined as follows. Let “structure A” be a CMOS silicon substrate alone (low-resistivity support substrate 102). Let “structure B” be a doped epitaxial layer on a CMOS silicon substrate (that is, a doped device layer, but no EMI immunity layer). And let “structure C” be a CMOS silicon substrate with a high-resistivity silicon epitaxial layer and a doped silicon epitaxial layer as in FIG. 1B (that is, an EMI-resistant semiconductor structure). The structures of FIG. 1A can also be considered an EMI-resistant semiconductor structure.

In some embodiments, at cross sectional line AA′, the induced current is reduced by about 95% for the EMI-resistant semiconductor structure as compared to the CMOS silicon substrate alone (e.g., V_{AA′} reduced from about 2300 μV (structure A) to about 80 μV (structure C)). At cross sectional line AA′, the induced current is reduced by about 95% for the EMI-resistant semiconductor structure as compared to the doped epitaxial layer on the CMOS silicon substrate (e.g., V_{AA′} reduced from about 2200 μV (structure B) to about 80 μV (structure C)). At cross sectional line CC′, the induced current is reduced by about 95% for the EMI-resistant semiconductor structure as compared to the CMOS silicon substrate alone (e.g., V_{CC′} reduced from about 2400 μV (structure A) to about 100 μV (structure C)). At cross sectional line CC′, the induced current is reduced by about 95% for the EMI-resistant semiconductor structure as compared to the doped epitaxial layer on the CMOS silicon substrate (e.g., V_{CC′} reduced from about 2400 μV (structure B) to about 100 μV (structure C)). These performance gains are for the induced current in the direction perpendicular to magnetic field 402.

Though induced currents parallel to magnetic field 402 tend to be weaker, these currents can also be reduced nonetheless. At cross sectional line BB′, the induced current is reduced by about 95% for the EMI-resistant semiconductor structure as compared to the CMOS silicon substrate alone (e.g., V_{BB′} reduced from about 35 μV (structure A) to about 1.5 μV (structure C)). At cross sectional line BB′, the induced current is reduced by about 95% for the EMI-resistant semiconductor structure as compared to the doped epitaxial layer on the CMOS silicon substrate (e.g., V_{BB′} reduced from about 35 μV (structure B) to about 1.5 μV (structure C)). At cross sectional line DD′, the induced current is reduced by about 98% for the EMI-resistant semiconductor structure as compared to the CMOS silicon substrate alone (e.g., V_{DD′} reduced from about 170 μV (structure A) to about 4 μV (structure C)). At cross sectional line DD′, the induced current is reduced by about 98% for the EMI-resistant semiconductor structure as compared to the doped epitaxial layer on the CMOS silicon substrate (e.g., V_{DD′} reduced from about 160 μV (structure B) to about 4 μV (structure C)).

On-chip integrated circuits 200 and 300 of FIGS. 2 and 3 are examples of circuits that can benefit from the EMI reduction afforded by the high-resistivity support substrate 102 of FIG. 1A or EMI immunity layer 104 of FIG. 1B. The EMI reduction can be greater than about 95% as explained above in reference to FIG. 4, which can greatly reduce signal noise from on-chip integrated circuit 200 and enhance device reliability and accuracy. It was explained above that noise currents from photodiode 202 of FIG. 2 can manifest as increased output noise at output 212. By implementing the high-resistivity support substrate 102 of FIG. 1A or EMI immunity layer 104 of FIG. 1B in on-chip integrated circuit 200 of FIG. 2, surface currents at photodiode 202 can be reduced by greater than about 95%, resulting in a commensurate reduction of output noise (a more reliable and accurate on-chip integrated circuit 200). Similarly, it was explained above that integrated BJTs (e.g., transistors 302 and 304 of FIG. 3) can be vulnerable to surface voltage variation due to EMI and, therefore, manifest as noise at output 308 and cause inaccurate temperature readings. By implementing the high-resistivity support substrate 102 of FIG. 1A or EMI immunity layer 104 of FIG. 1B on-chip integrated circuit 300 of FIG. 3, surface voltage variations at transistors 302 and 304 can be reduced by greater than about 95%, resulting in a commensurate reduction of noise (a more reliable and accurate on-chip integrated circuit 300). It is within the spirit and scope of the present disclosure that the high-resistivity support substrate 102 of FIG. 1A and EMI immunity layer 104 of FIG. 1B can be implemented in other EMI-susceptible semiconductor devices.

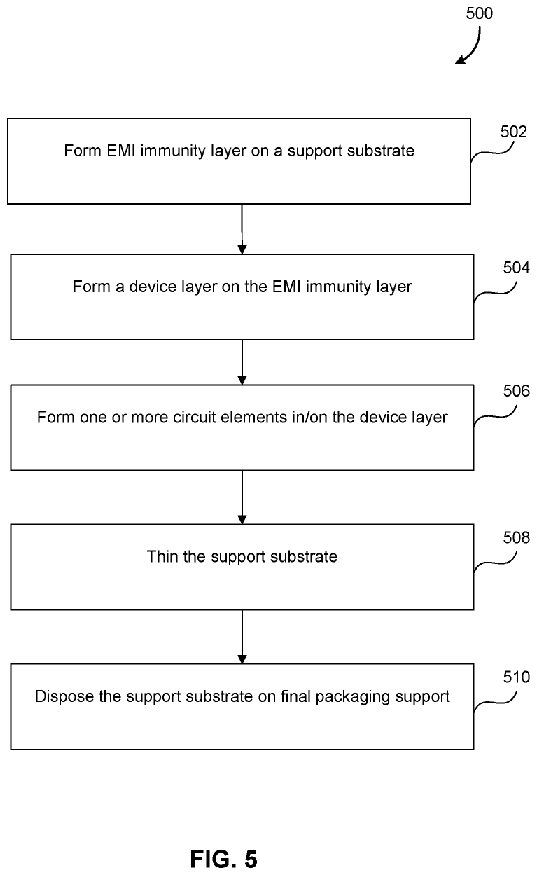

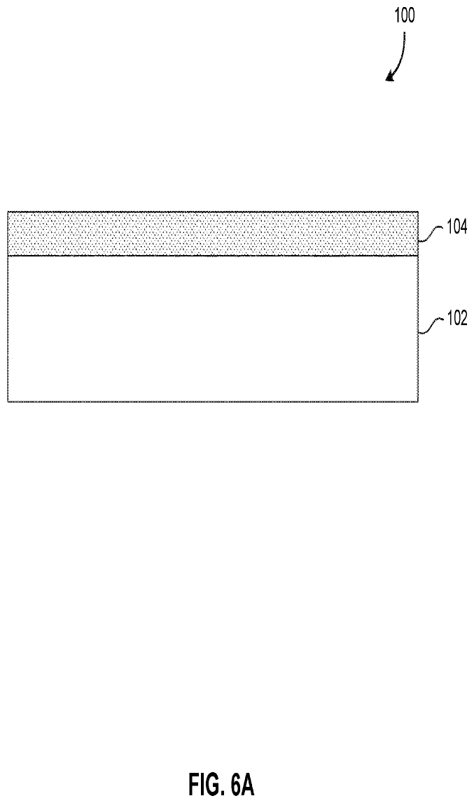

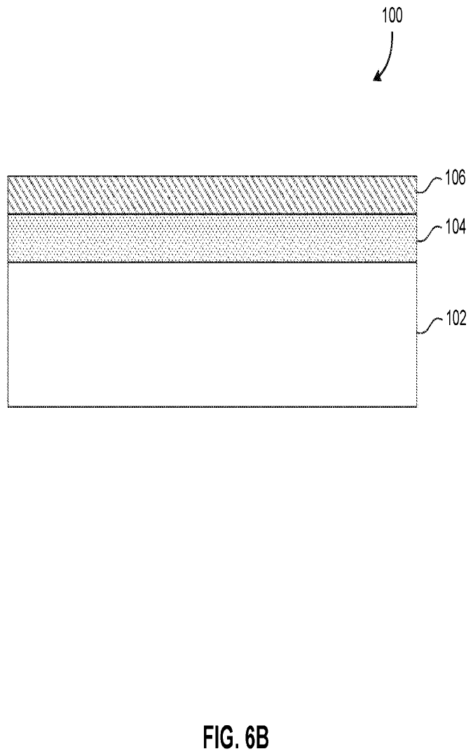

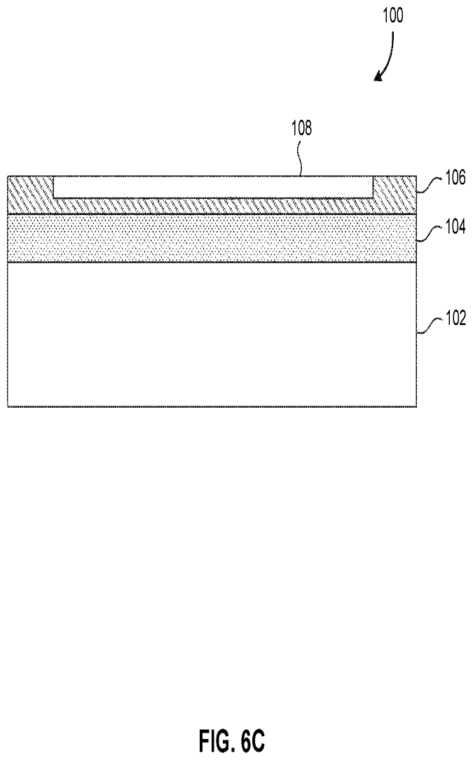

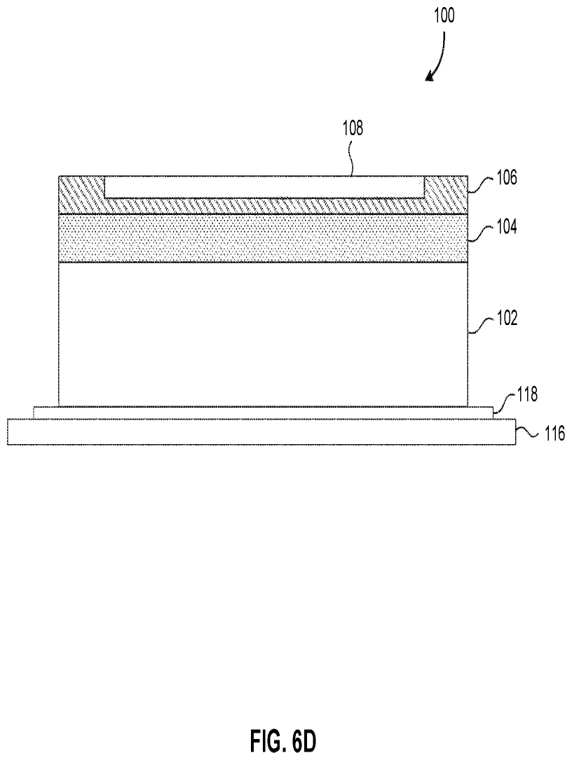

FIGS. 5 and 6A-6D show a method 500 for fabricating semiconductor structure 100′ of FIG. 1B, as well as an illustration of semiconductor structure 100′ at various stages of method 500, according to some embodiments. In some embodiments, additional operations can be performed between, or in place of, various operations of method 500. The additional operations can be provided before, during, and/or after method 500. Moreover, not all operations may be needed to perform the disclosure provided herein. Additionally, some of the operations can be performed simultaneously or in a different order than shown in FIG. 5. Method 500 will be described in reference to some of the structures described in reference to FIGS. 1B and 6A-6D.

In some embodiments, at operation 502, EMI immunity layer 104 is formed on support substrate 102 as shown in FIG. 6A. The formation of EMI immunity layer 104 is performed such that EMI immunity layer 104 is a silicon layer with a resistivity greater than that of support substrate 102 and a thickness less than that of support substrate 102. EMI immunity layer 104 can be formed using a suitable semiconductor layering technique (e.g., epitaxial growth or deposition) with or without adjustments from ion implantations. In some embodiments, forming EMI immunity layer 104 includes epitaxially growing a layer of high-resistivity silicon on support substrate 102.

In some embodiments, at operation 504, device layer 106 is formed on EMI immunity layer 104 as shown in FIG. 6B. The formation of device layer 106 is performed such that device layer 106 has a resistivity lower than that of EMI immunity layer 104 and a thickness less than that of support substrate 102. Device layer 106, which is a doped epitaxial layer, can be formed using a suitable semiconductor layering technique (e.g., epitaxial growth or deposition). In some embodiments, the formation of device layer 106 includes epitaxially growing a layer of silicon on EMI immunity layer 104 (e.g., the layer of high-resistivity silicon introduced at operation 504). The formation of device layer 106 also includes doping the layer of silicon to adjust the resistivity of the doped epitaxial layer. Furthermore, thicknesses, resistivities, and dopant concentrations of support substrate 102, EMI immunity layer 104, and device layer 106 can be those described above in reference to FIG. 1B.

In some embodiments, at operation 506, one or more circuit elements 108 are formed in/on device layer 106 as shown in FIG. 6C. One or more circuit elements can include passive devices, transistors, and interconnects. One or more circuit elements can be arranged as shown in FIGS. 3 and 4.

In some embodiments, at operation 508, support substrate 102 is thinned. The thinning operation can be performed using any suitable material removal technique(s) (e.g., grinding, chemical mechanical polish or etching).

In some embodiments, at operation 510, support substrate 102 is disposed on final packaging support 116 as shown in FIG. 6D (or EMI immunity layer 104 is disposed on final packaging support 116 if support substrate 102 is removed as part of the thinning process). If contact layer 118 is desired, contact layer 118 can be disposed on final packaging support 116 so as to contact support substrate 102 (or contact EMI immunity layer 104).

The modification of the starting wafer for IC manufacturing can be performed provide the lowest overall cost of manufacture of the IC with the addition of the EMI immunity layer, according to some embodiments. A significant change in the starting wafer for IC fabrication can trigger a qualification process that can be both expensive and time consuming. However, in some cases, upfront investment to allow a custom wafer to be used therefore may not achieve a viable commercial solution. The limitations imposed by an IC manufacturer can be counter to efforts to increase EMI immunity layer. Or the tolerances to qualify the modified wafer can present exorbitant costs and/or time delays. In FIGS. 7, 8A-8D, and 9, a method to replace the mechanical support portion of the IC wafer (after IC manufacturing is completed) is described. The mechanical support portion of the original wafer is removed and replaced with a new mechanical support with optimized properties for electromagnetic immunity.

This embodiment has at least the following advantages:
(1) No disturbance of the base IC manufacturing flow and hence no prompting of special qualifications.
(2) The replacement mechanical wafers properties are selected for mechanical support and maximum electromagnetic immunity. This allows higher resistivity materials to be employed to achieve increased EMI immunity and allows the use of insulating materials between the device layers and the mechanical support, providing a practical equivalent of a substrate with near infinite resistivity.
(3) Can be implemented entirely as part of packaging operations, affording freedom to adjust and adapt the EMI immunity properties for different applications.

This solution presents a modest additional recurring cost and a modest additional processing time during the packaging process.

FIGS. 7 and 8A-8D and 9 show a method 700 for further removal of a substantial portion of the original IC wafer of semiconductor structure 100 of FIG. 1B and the replacement of the mechanical support elements with a new support element 902. The new support element 902 can be electrically isolated from the device layer of the original IC wafer by an insulating layer and can also have high resistivity.

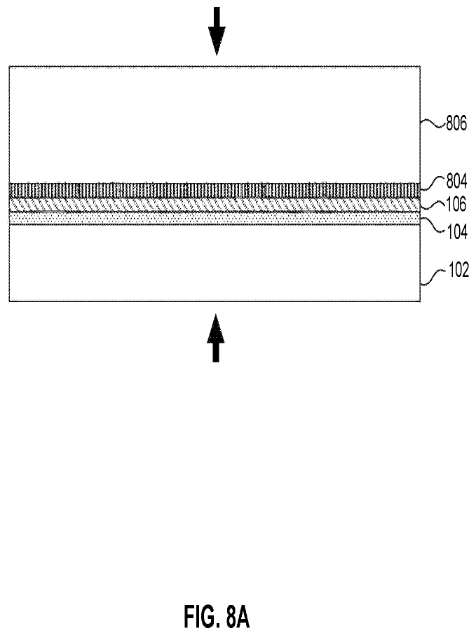

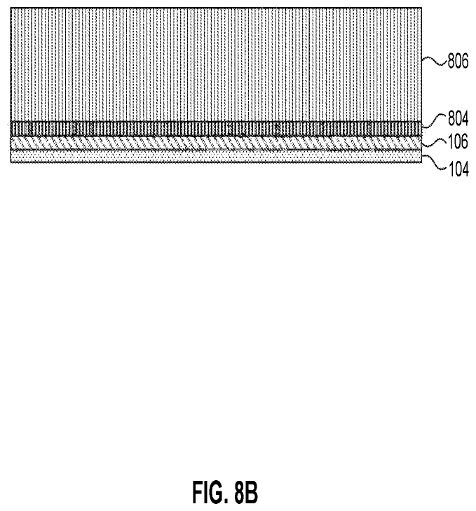

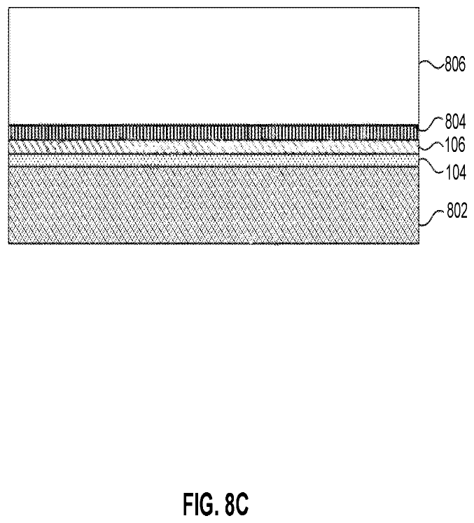

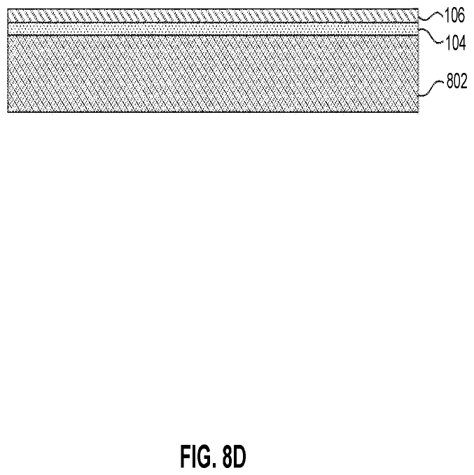

FIGS. 8A-8D illustrate semiconductor structure 100 at various stages of method 700. Shown in FIGS. 8A, 8B, 8C, and/or 8D are a support substrate 806 (e.g., a temporary mechanical wafer) with a layer of adhesive 804, semiconductor structure 100′ having the layers described in reference to FIG. 1B, and a support substrate 802 (e.g., a high-resistivity permanent wafer for packaging that can act as final packaging support 116 of FIG. 1B).

In some embodiments, additional operations can be performed between, or in place of, various operations of method 700. The additional operations can be provided before, during, and/or after method 700. Moreover, not all operations may be needed to perform the disclosure provided herein. Additionally, some of the operations can be performed simultaneously or in a different order than shown in FIG. 7. Method 700 will be described in reference to some of the structures described in reference to FIGS. 1B, 8A, 8B, 8C, and 8D.

In some embodiments, the base wafer used in IC manufacture receives no changes or modifications for enhanced electromagnetic immunity. In some embodiments, semiconductor device 100 can be prepared as described in reference to FIGS. 1-6. Support substrate 102 can be a CMOS base wafer, which can be doped (e.g., dopant concentration of about 1×10¹⁴ cm⁻³ to about 1×10¹⁶ cm⁻³). Performance of some semiconductor devices can be enhanced by replacing the doped substrate (low resistivity) with one having a high resistivity. Method 700 includes operations for transferring semiconductor devices on a doped base substrate to another substrate having a higher resistivity.

In some embodiments, at operation 702, device layer 106 of semiconductor device 100 can be bonded to support substrate 806 (e.g., a second support substrate) using adhesive 804 as shown in FIG. 8A. Support substrate 102 can be referred to as a “first support substrate.” Support substrate 806 can be a temporary, sacrificial wafer.

In some embodiments, at operation 704, support substrate 102 of semiconductor device 100′ is removed such that a surface of EMI immunity layer 104 is exposed as shown in FIG. 8B.

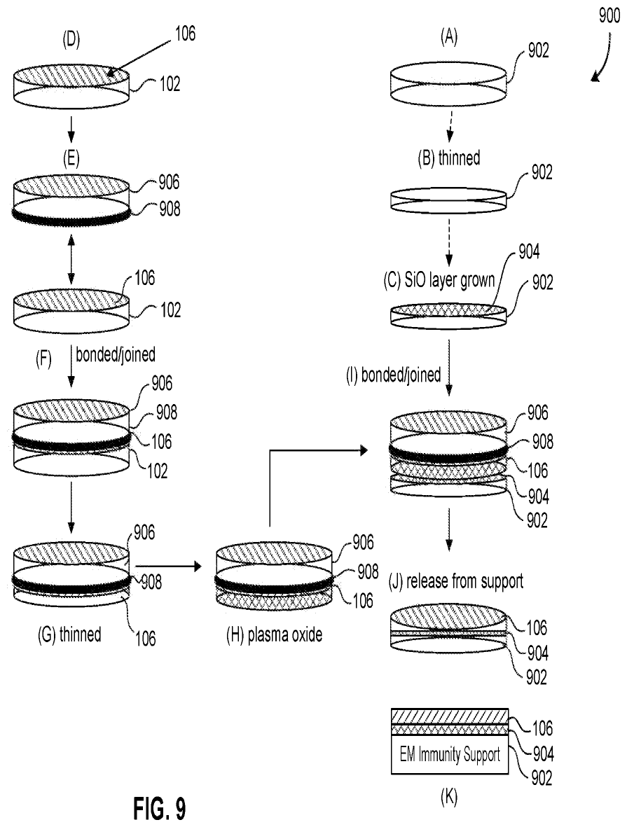

The removal of support substrate 102 can be performed using any suitable material removal technique(s) (e.g., grinding, chemical mechanical polish or etching). The removal process can be performed to about 1 μm to about 4 μm absolute accuracy across an entire wafer, thereby allowing a buffer layer (described in reference to FIG. 9) or original EMI immunity layer 104 to be safely retained as desired. EMI immunity layer 104 and device layer 106 remain adhered to support substrate 806 after the removal of support substrate 102. A role of support substrate 806 is to provide temporary support to EMI immunity layer 104 (and/or the buffer layer described in reference to FIG. 9) and device layer 106 during and after the removal of support substrate 102.

In some embodiments, at operation 706, the exposed surface of EMI immunity layer 104 is bonded to a support substrate 802 (e.g., using a polymer film). Support substrate 802 can be referred to as a “third support substrate.” The bonding at operation 706 can be permanent in preparation for the packaging of semiconductor device 100′. Support substrate 802 takes the place of support substrate 102. Support substrate 802 is different in that it has a very high resistivity (e.g., high-resistivity silicon wafer with resistivity of about 1×10² to about 10⁶ Ω-cm) compared to a resistivity of a CMOS silicon substrate (e.g., about 1×10⁻³ to about 10 Ω-cm), thereby enhancing the EMI immunity effect that was described above.

FIG. 8C illustrates the process at the intermediate state of operation 706 in the process flow where the mechanical support substrate 806 is still temporarily bonded to the front of device layer 106 of the original wafer and the new mechanical support element, support substrate 802, is permanently bonded to device layer 106 plus any EMI immunity layer 104 and/or buffer layer that is present. Referring to FIG. 8C, support substrate 802 is shown to be bonded to EMI immunity layer 104 (or the buffer layer). Though not shown, it is envisaged that an intervening oxide layer can be present between EMI immunity layer 104 (or the buffer layer) and support substrate 802. The oxide layer can be formed by oxidation and/or deposition methods. An example method is described below in reference to FIG. 9. When suitable plasma activation has been applied to the oxide surfaces, a permanent bond can form when oxide layers are pressed together and annealed at relatively low temperatures. Annealing temperatures, which can form a secure oxide-to-oxide bond, are well below temperatures that would adversely affect the IC devices present on the wafer (e.g., about 250° C.). Oxide bonding can be an alternative to provide an insulating layer between the active device area of the original wafer and the new mechanical support element. This dielectric interface provides isolation between eddy currents introduced by electromagnetic interference in the new support substrate 802 and device layer 106. This effectively provides near infinite resistivity and eliminates any significant interaction between the minute currents in the high resistivity substrate support 802 and device layer 106.

At operation 708, support substrate 806 is removed from device layer 106. The removal of support substrate 806 is accomplished by methods that release the bond formed at operation 706. Adhesive 804 can be removed at this operation. Adhesive 804 can be solvent soluble (e.g., removed using a solvent) or by thermal treatments followed by mechanical actions. The final result illustrated in FIG. 8D relates to a direct silicon bond in which there is electrical continuity between the new support substrate 802 and the original device layer 106. And, though not shown, the use of an intervening oxide layer as described above provides an option for maximum electromagnetic immunity in which joining of device layer 106 and the new support layer 802 is performed by oxide to oxide bonding to provide dielectric isolation.

FIG. 9 shows a flow diagram 900 for modifying a mechanical support element after completion of IC manufacturing operations, according to some embodiments. In particular, FIG. 9 shows an example implementation of the flow of FIG. 7 to implement oxide-to-oxide bonding. The solution presented in flow diagram 900 avoids issues associated with use of high-resistivity starting wafers in the IC manufacturing process. The high-resistivity support wafer is added after IC fabrication is completed and full isolation is provided between device layer and a new mechanical support layer. The substitution of the original mechanical support portion of a wafer used for a new support wafer allows optimization of the EMI immunity properties of the final packaged element.

Flow diagram 900 can be implemented using one or more of the operations described above with reference to FIGS. 1B, 7, 8A, 8B, 8C, and 8D.

In some embodiments, referring to (A) in FIG. 9, manufacturing a high-resistivity wafer 902 that is uniformly doped is easier and less expensive than manufacturing a special starting wafer with multiple doping zones through epitaxy. Furthermore, support wafer 902 does not have to be compatible with high temperature process methods and impurity constraints for a CMOS manufacturing line. Referring to (B) in FIG. 9, High-resistivity wafer 902 is thinned to a target thickness. As an alternative, the thinning can also occur after the high resistivity mechanical support wafer has been joined to device layer 106. Referring to (C) in FIG. 9, the thinned high-resistivity wafer 902 is polished to a high-quality surface finish and a high-quality thermal oxide 904 is grown on at least one surface of the polished high-resistivity wafer 902.

In a separate IC manufacturing process stream, referring to (D) in FIG. 9, a CMOS ASIC wafer is produced. The CMOS ASIC wafer may or may not have resistivity support layer 102 (for enhanced EMI immunity). The CMOS ASIC wafer will be processed to preserve intact and undisturbed device layer 106.

Referring to (E) in FIG. 9, a support structure 906 is provided with a temporary polymer film 908 (for bonding) provided on one side of support structure 906. Temporary polymer film 908 is removable. Referring to (F) in FIG. 9, the device side of the completed IC wafer (device layer 106) is bonded to support structure 906 using temporary polymer film 908. Referring to (G), the arrangement protects the sensitive circuits of device layer 106 while the non-device side of the IC wafer is thinned by grinding and polishing so as to leave behind the critical device zone with a small buffer zone for safety.

In some embodiments, there can be no EMI immunity layer 104, as the base wafer for IC manufacture may not contain the feature. The removal process is controlled to stop before complete removal, leaving a buffer layer or zone. The buffer layer thickness is a portion of the original wafer which is close to active devices to maximize EMI immunity, but far enough from active devices that the removal process does not inflict any damage on the active devices in device layer 106. Such polishing and grinding can be done very precisely with errors down to less than a fraction of a micron over a silicon wafer. This allows device layer 106 to be separated safely from support substrate 102.

Referring to (H) in FIG. 9, after the grind and polish, the exposed underside of device layer 106 is oxidized to form a thin layer of silicon oxide with a plasma-enhanced oxidation. The plasma-enhanced oxidation promotes fusion with another oxide surface at low temperatures. Referring to (I) in FIG. 9, the surviving device layer 106, supported by support structure 906, is then oxide-oxide bonded at low temperature with oxide 904 of high-resistivity wafer 902. At certain temperatures and pressures, the oxide layers fuse to create a silicon-oxide-silicon sandwich with sufficient strength and flatness. Referring to (J) in FIG. 9, the temporary support structure 906 is then removed by leveraging the removable temporary polymer film 908. Referring to (K) in FIG. 9, the final structure shown includes the thinned high-resistivity support wafer 902, the layer of oxide 904 (provides isolation), and the isolated device layer 906. The approach provides RF immunity from at least the following considerations.
(1) Device layer 106 is unchanged and undamaged. A thickness of device layer 106 need only be concerned with proper electronic function (as opposed to providing mechanical support). Consequently, an “antennae volume” in which electromagnetic aggressors can induce currents or potentials is minimized. The small volume of silicon can be well grounded due to the proximity of the circuitry in device layer 106 to the ground wiring and well contacts that serve the IC design.
(2) Device layer 106 is further electrically isolated owing to the presence of layer of oxide 904. Oxide 904 prevents any current induced in high-resistivity support wafer 902 from effecting the circuit and reduces any capacitive coupling of induced potentials in high-resistivity support wafer 902.
(3) A thickness of high-resistivity wafer 902 is only constrained by packaging specifications. During manufacture of high-resistivity wafer 902, doping levels can be adjusted to minimize interaction with electromagnetic fields or electric fields. For example, if induced currents are a concern, high-resistivity support wafer 902 can have high resistivity to minimize current. If eddy currents creating stray magnetic fields are a concern, high-resistivity support wafer 902 can have low resistivity and be robustly grounded to the floor of the package to shunt induced currents to a fixed potential. The methods described herein allow engineering semiconductor devices having immunity to electric fields, magnetic fields, and high frequency electromagnetic fields by using modified support structures to package a thin active device volume of an IC.

Embodiments in reference to FIG. 9 can also be extended to additional constraints of the process design. Using a method similar to the embodiment illustrated in FIG. 9, semiconductor device 100 (with support substrate 102 and device layer 106) can be prepared with vias for planned connections with other structures (e.g., final packaging support 116 in FIG. 1B). Support wafer 902 can be provided with connection structures. On semiconductor device 100, deep metal filled holes or vias are provided to a depth that extends below device layer 106 such that connections can be made to connection structures on support wafer 902.

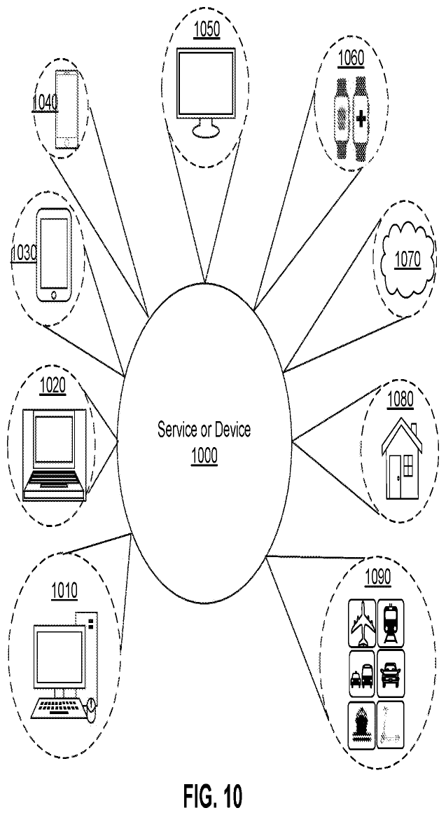

FIG. 10 shows an illustration of exemplary systems or devices that can include the disclosed embodiments. System or device 1000 can incorporate one or more of the disclosed embodiments in a wide range of areas. For example, system or device 1000 can be implemented in one or more of a desktop computer 1010, a laptop computer 1020, a tablet computer 1030, a cellular or mobile phone 1040, and a television 1050 (or a set-top box in communication with a television).

Also, system or device 1000 can be implemented in a wearable device 1060, such as a smartwatch or a health-monitoring device. In some embodiments, the smartwatch can have different functions, such as access to email, cellular service, and calendar functions. Wearable device 1060 can also perform health-monitoring functions, such as monitoring a user's vital signs and performing epidemiological functions (e.g., contact tracing and providing communication to an emergency medical service). Wearable device 1060 can be worn on a user's neck, implantable in user's body, glasses or a helmet designed to provide computer-generated reality experiences (e.g., augmented and/or virtual reality), any other suitable wearable device, and combinations thereof.

Further, system or device 1000 can be implemented in a server computer system, such as a dedicated server or on shared hardware that implements a cloud-based service 1070. System or device 1000 can be implemented in other electronic devices, such as a home electronic device 1080 that includes a refrigerator, a thermostat, a security camera, and other suitable home electronic devices. The interconnection of such devices can be referred to as the “Internet of Things” (IoT). System or device 1000 can also be implemented in various modes of transportation 1090, such as part of a vehicle's control system, guidance system, and/or entertainment system.

The systems and devices illustrated in FIG. 10 are merely examples and are not intended to limit future applications of the disclosed embodiments. Other example systems and devices that can implement the disclosed embodiments include portable gaming devices, music players, data storage devices, and unmanned aerial vehicles.

One or more embodiments described herein are directed to increasing immunity to electromagnetic interference by fabrication of devices on a custom wafer created by epitaxial growth methods to provide a low resistivity layer for electromagnetic immunity in close contact to a device formation layer with properties conducive to integrated circuit fabrication. The thickness and concentration of the electromagnetic immunity layer is engineered to provide an effective increase in electromagnetic immunity for the device application. Electromagnetic immunity can be further enhanced by removal of a significant proportion of the original device fabrication supporting wafer. Additional mechanical support with electromagnetic immunity from selection of high resistivity silicon and/or dielectric isolation from the device layer can be provided as part of the packaging process. One or more embodiments described herein are also directed to increasing immunity to electromagnetic interference by fabrication of devices on a starter CMOS wafer and subsequent replacement of a substantial portion of the starter wafer with a new mechanical support wafer during packaging operations. To design a custom wafer substrates for fabrication of devices and/or integration into final packaging, estimates of the impact of magnetically induced currents in the substrate can be achieved according to Eq. 1 above. Designing the custom wafer substrate can include using computational analysis correlated with measured electromagnetic immunity from similar circuits to estimate the improvement in electromagnetic immunity achieved by alternate designs and executions of the addition of an electromagnetic immunity layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an electromagnetic interference (EMI) immunity layer having a first resistivity and a first thickness; and
a doped epitaxial layer on the EMI immunity layer, the doped epitaxial layer having a second resistivity and a second thickness,
wherein a sum of thicknesses is defined by a combination of the first thickness and the second thickness,
wherein a first ratio is the sum of thicknesses to the second thickness and a second ratio is the second resistivity to the first resistivity, and
wherein a product of the first ratio and the second ratio is equal to or less than about 1.

2. The structure of claim 1, wherein the first resistivity is over 100,000 times greater than the second resistivity.

3. The structure of claim 1, wherein the first thickness is over 3 times less than the second thickness.

4. The structure of claim 1, wherein the first thickness is between about 60 μm and about 200 μm.

5. The structure of claim 1, further comprising a support substrate having a third thickness and a third resistivity, wherein the EMI immunity layer is disposed on the support substrate.

6. The structure of claim 5, wherein the third resistivity is over 100 times less than the first resistivity.

7. The structure of claim 5, wherein the third thickness is 4 times greater than the first thickness.

8. The structure of claim 1, wherein the doped epitaxial layer comprises dopants with a concentration greater than about 1×10¹⁷ cm⁻³.

9. A semiconductor device, comprising:
a support substrate comprising an electromagnetic interference (EMI) immunity layer having a first resistivity and a first thickness; and
a device layer in contact with a top surface of the support substrate and comprising one or more circuit elements disposed in a doped epitaxial silicon layer having a second resistivity and a second thickness,
wherein a sum of thicknesses is defined by a combination of the first thickness and the second thickness,
wherein a first ratio is the sum of thicknesses to the second thickness and a second ratio is the second resistivity to the first resistivity, and
wherein a product of the first ratio and the second ratio is equal to or less than about 1.

10. The semiconductor device of claim 9, wherein the one or more circuit elements comprise a passive device, a transistor device, and an interconnect.

11. The semiconductor device of claim 9, wherein the doped epitaxial silicon layer comprises p-type dopants with a concentration greater than about 1×10¹⁷ cm⁻³.

12. The semiconductor device of claim 9, wherein the first dopant level is zero.

13. The semiconductor device of claim 9, wherein the first thickness range is from about 60 μm to about 200 μm.

14. The semiconductor device of claim 9, wherein the support substrate further comprises a support layer having a third thickness from about 100 μm to about 120 μm.

15. The semiconductor device of claim 9, wherein the EMI immunity layer has a resistivity greater than about 200 k Ω-cm.

16. A method, comprising:
forming a doped epitaxial layer on a support substrate comprising an electromagnetic interference (EMI) immunity layer having a first resistivity and a first thickness,
wherein the doped epitaxial layer has a second resistivity and a second thickness,
wherein a sum of thicknesses is defined by a combination of the first thickness and the second thickness,
wherein a first ratio is the sum of thicknesses to the second thickness and a second ratio of the second resistivity to the first resistivity, and
wherein a product of the first ratio and the second ratio is equal to or less than about 1; and
forming one or more circuit elements in the doped epitaxial layer.

17. The method of claim 16, further comprising:
thinning the support substrate.

18. The method of claim 16, further comprising forming the EMI immunity layer, wherein forming the doped epitaxial layer and forming the EMI immunity layer are performed such that the product of the first ratio and the second ratio is equal to or less than about 0.1.

19. The method of claim 18, wherein forming the doped epitaxial layer comprises:
epitaxially growing a layer of silicon on the layer EMI immunity layer; and
doping the layer of silicon to adjust the resistivity of the doped epitaxial layer such that the product of the first ratio and the second ratio is equal to or less than about 0.1.

20. The method of claim 16, wherein forming the one or more circuit elements comprises forming one or more of a passive device, a transistor device, and an interconnect in the doped epitaxial layer.
